(19) United States
(12) Patent Application Publication
(10) Pub. No.: US 2026/0144099 A1
(43) Pub. Date: May 21, 2026

(54) SEMICONDUCTOR STRUCTURE AND MANUFACTURING METHOD THEREFOR, AND SEMICONDUCTOR DEVICE

(71) Applicant: CXMT Corporation, Hefei (CN)

(72) Inventors: Xiaoping Liu, Hefei (CN); Dan Xu, Hefei (CN); Ming-hui Huang, Hefei (CN)

(73) Assignee: CXMT Corporation, Hefei (CN)

(21) Appl. No.: 19/418,246

(22) Filed: Dec. 12, 2025

Related U.S. Application Data
(63) Continuation of application No. PCT/CN2025/080729, filed on Mar. 5, 2025.

(30) Foreign Application Priority Data
Nov. 15, 2024 (CN) 202411640113.8

(51) Int. Cl. H10W 70/63; H10D 80/20; H10W 20/20; H10W 70/05

(52) U.S. Cl. CPC H10W 70/635; H10D 80/215; H10W 20/213; H10W 70/095

(57) ABSTRACT

A semiconductor structure includes: an interposer and a capacitor. The interposer has holes and trenches extending from a top surface of the interposer toward an inside of the interposer. The capacitor located in the holes and the trenches includes a first electrode layer, a capacitor dielectric layer, and a second electrode layer which are sequentially stacked; the capacitor dielectric layer covers a surface of the first electrode layer, the second electrode layer covers a surface of the capacitor dielectric layer. The trenches extend in a direction parallel to the top surface of the interposer and communicate with a plurality of holes spaced apart in the direction, a width dimension of the holes is larger than a width dimension of the trenches. The semiconductor structure has the advantages of large capacity, rapid charge and discharge, and high integration, and the layout of the semiconductor structure can better solve the stress problem.

### CROSS-REFERENCE TO RELATED APPLICATIONS

This application is a continuation of International Patent Application No. PCT/CN2025/080729, filed on Mar. 5, 2025, which claims the benefit of Chinese Patent Application No. 202411640113.8, titled "SEMICONDUCTOR STRUCTURE AND MANUFACTURING METHOD THEREFOR, AND SEMICONDUCTOR DEVICE", filed with the China National Intellectual Property Administration (CNIPA) on November 15, 2024, the disclosures of which are incorporated herein by reference in their entireties.

### TECHNICAL FIELD

Embodiments of the present disclosure relate to the technical field of semiconductors, and in particular, to a semiconductor structure and a manufacturing method therefor, and a semiconductor device.

### BACKGROUND

To increase the integration of semiconductor structures, many chips may be stacked and welded together, for example, to form a 3-dimensional stack (3-dimensional stack, 3DS) memory. Therefore, the original 2D layout may be expanded to 2.5D (between 2D and 3D packaging) or 3D, thereby greatly increasing the density of chips. In the field of advanced packaging technologies, especially in 2.5D and 3D packaging technologies, interposer packaging is widely used; that is, a plurality of chips (dies) are disposed on a substrate through an interposer apparatus, and different chips can receive signals from other chips or transmit signals to other chips through the interposer apparatus, thereby increasing the signal density of the whole package while achieving the advantage of reducing the whole volume.

In the interposer apparatus, to maintain the stability of signals, deep trench capacitor structures (deep trench capacitor structures, DTCs) are usually used to prevent signal lines from interfering with each other. However, the structure design of the deep trench capacitor structure in the prior art has significant limitations, and the performance of the structure needs to be further enhanced.

### SUMMARY

According to a first aspect of embodiments of the present disclosure, a semiconductor structure is provided. The semiconductor structure includes: an interposer and a capacitor. The interposer is provided with holes and trenches extending from a top surface of the interposer toward an inside of the interposer. The capacitor is located in the holes and the trenches; the capacitor includes a first electrode layer, a capacitor dielectric layer, and a second electrode layer which are sequentially stacked; the capacitor dielectric layer covers a surface of the first electrode layer, and the second electrode layer covers a surface of the capacitor dielectric layer. Each of the trenches further extends in a preset direction parallel to the top surface of the interposer and communicates with a plurality of holes spaced apart in the preset direction, a width dimension of each of the holes is larger than a width dimension of the trench, and a direction of width dimensions is parallel to the top surface of the interposer and perpendicular to the preset direction.

According to a second aspect of the embodiments of the present disclosure, a method for manufacturing a semiconductor structure is provided. The method for manufacturing a semiconductor structure includes: providing an interposer; forming holes and trenches extending from a top surface of the interposer toward an inside of the interposer in the interposer; and forming a capacitor, composed of a first electrode layer, a capacitor dielectric layer, and a second electrode layer which are sequentially stacked, in the holes and the trenches, where the capacitor dielectric layer covers a surface of the first electrode layer, and the second electrode layer covers a surface of the capacitor dielectric layer. Each of the trenches further extends in a preset direction parallel to the top surface of the interposer and communicates with a plurality of holes spaced apart in the preset direction, a width dimension of each of the holes is larger than a width dimension of the trench, and a direction of width dimensions is parallel to the top surface of the interposer and perpendicular to the preset direction.

According to a third aspect of the embodiments of the present disclosure, a semiconductor device is provided. The semiconductor device includes: the semiconductor structure according to any one of the foregoing embodiments; and chips, located above the semiconductor structure, where the chips and the semiconductor structure are electrically connected through solder bumps and/or pads.

### BRIEF DESCRIPTION OF DRAWINGS

FIG. 1 is a schematic diagram of provision of an interposer according to an exemplary embodiment;

FIG. 2 is a schematic diagram of formation of holes and trenches according to an exemplary embodiment;

FIG. 3 is a schematic diagram of formation of holes and trenches according to another exemplary embodiment;

FIG. 4 is a schematic diagram of formation of a bottom dielectric layer according to an exemplary embodiment;

FIG. 5 is a schematic diagram of formation of a capacitor according to an exemplary embodiment;

FIG. 6 is a schematic diagram of formation of lead-out contact layers, first contact members, and second contact members according to an exemplary embodiment;

FIG. 7 is a schematic diagram of formation of lead-out contact layers, first contact members, and second contact members according to another exemplary embodiment;

FIG. 8 is a schematic layout diagram of a semiconductor structure according to an exemplary embodiment; and

FIG. 9 is a schematic diagram of a semiconductor device according to an exemplary embodiment.

### DESCRIPTION OF EMBODIMENTS

The technical solutions of the present disclosure will be further elaborated below with reference to the drawings and embodiments. While exemplary implementations of the present disclosure are shown in the drawings, it should be understood that the present disclosure may be implemented in various forms and should not be limited by the embodiments set forth herein. Rather, these embodiments are provided so that the present disclosure will be more thoroughly understood and the scope of the present disclosure will be fully conveyed to those skilled in the art.

The present disclosure is more specifically described in the following paragraphs with reference to the drawings by way of example. The advantages and features of the present disclosure will become apparent from the following description and claims. It should be noted that the drawings are all in a very simplified form and not to a precise scale, and are provided only for the purpose of facilitating a convenient and clear description of the embodiments of the present disclosure.

It will be understood that the meaning of “on”, “above”, and “over” in the present disclosure should be interpreted in the broadest manner such that “on” not only includes the meaning of “on” something with no intermediate feature or layer therebetween (i.e., directly on something) but also includes the meaning of “on” something with an intermediate feature or a layer therebetween.

In the embodiments of the present disclosure, the terms “first”, “second”, “third”, and the like are used for distinguishing similar objects and are not necessarily used for describing a particular order or sequence.

In the embodiments of the present disclosure, the term “layer” refers to a material portion that includes a region having a thickness. A layer may extend over the entirety of the underlying or overlying structure or may have an extent that is less than the extent of the underlying or overlying structure. Furthermore, a layer may be a region of a homogeneous or inhomogeneous continuous structure having a thickness less than the thickness of a continuous structure. For example, a layer may be located between the top surface and the bottom surface of a continuous structure, or a layer may be located between any pair of horizontal planes at the top surface and the bottom surface of the continuous structure. A layer may extend horizontally, perpendicularly, and/or along inclined surfaces. A layer may include a plurality of sub-layers.

It should be noted that unless conflicting, the technical solutions described in the embodiments of the present disclosure may be arbitrarily combined.

In the related art, the DTC structure is substantially in a deep-hole shape, and is usually fabricated simultaneously by adopting a process for forming through silicon vias (through silicon vias, TSVs) in the interposer. The inventors of the present disclosure found that: with the development of the 2.5D packaging technology, after the device dimension is further reduced, the capacitor area of the DTC structure is reduced; in addition, it is increasingly difficult to achieve the increase of capacitance density, and at the same time, along with the problems of increasingly severe stress in the support process and the like, it becomes increasingly important to find a new DTC structure design solution.

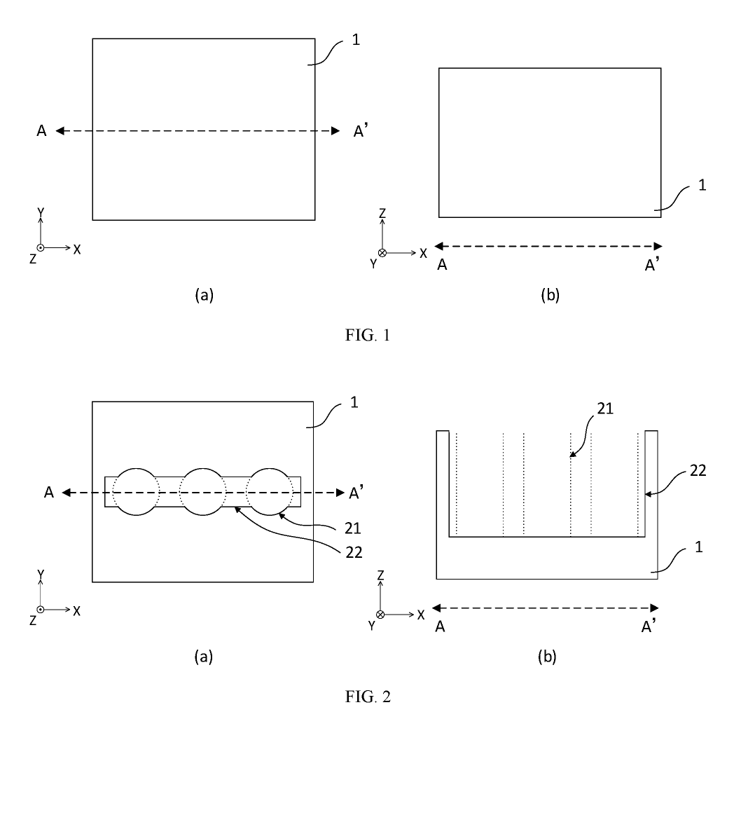

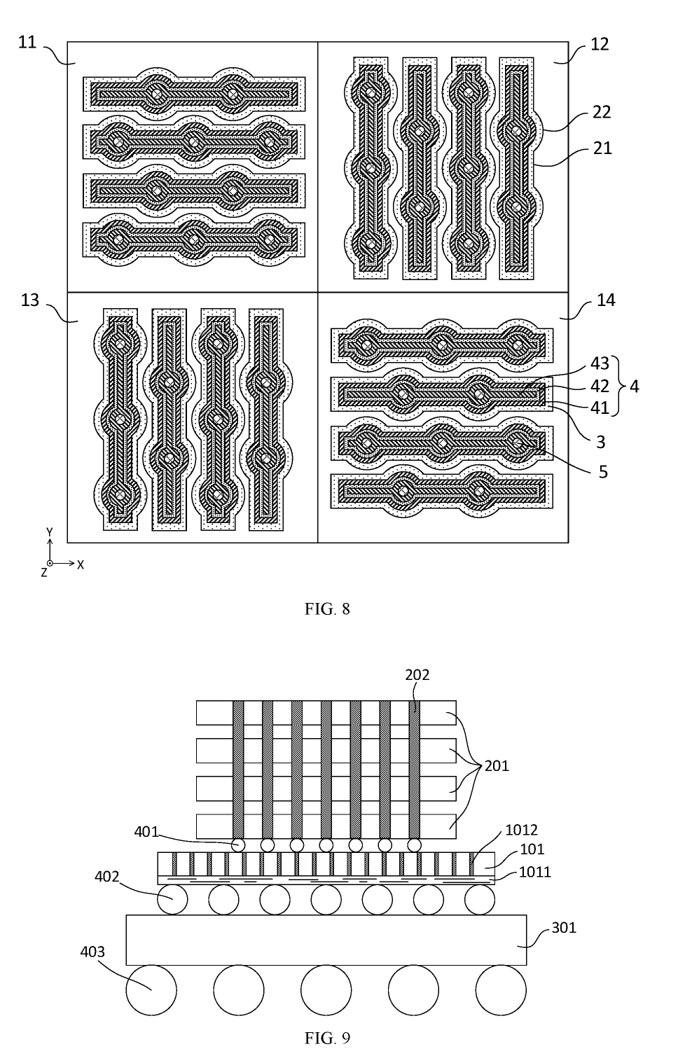

In view of the above technical problems, the present disclosure provides a semiconductor structure and a manufacturing method therefor, and a semiconductor device. The semiconductor structure and the manufacturing method therefor, and the semiconductor device exemplarily provided in the present disclosure will be specifically described below with reference to FIGS. 1 to 9. FIGS. 1 to 7 are schematic diagrams of a method for manufacturing a semiconductor structure according to various exemplary embodiments of the present disclosure; FIG. 8 is a schematic layout diagram of a semiconductor structure according to an exemplary embodiment of the present disclosure; FIG. 9 is a schematic diagram of a semiconductor device according to an exemplary embodiment of the present disclosure.

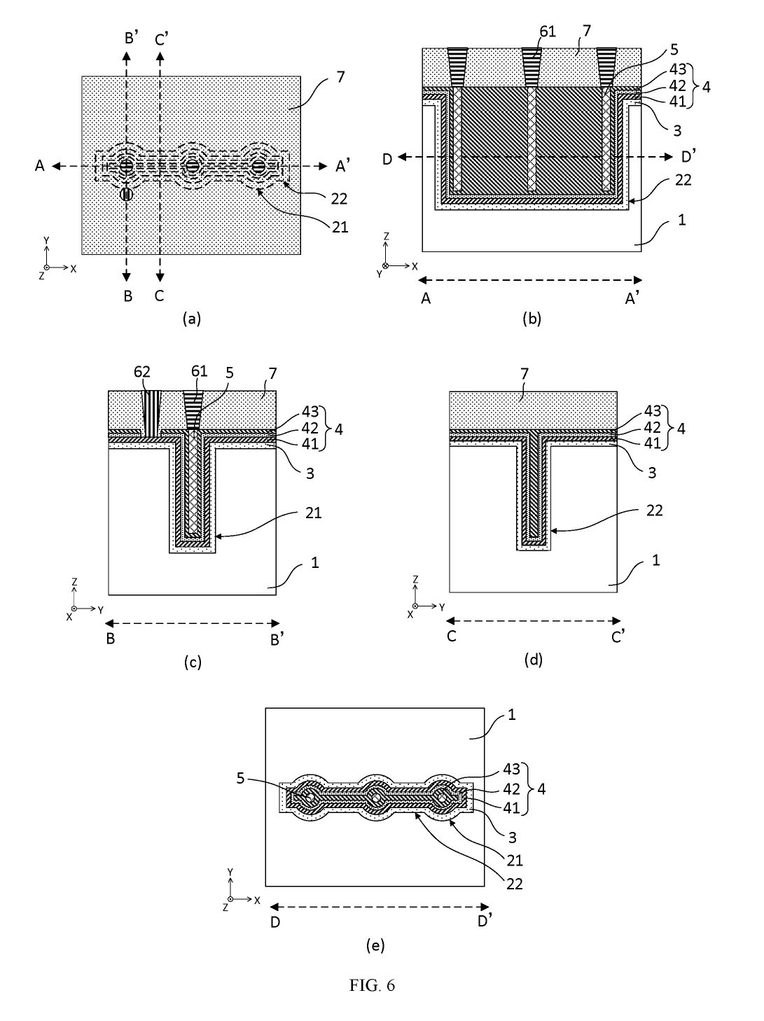

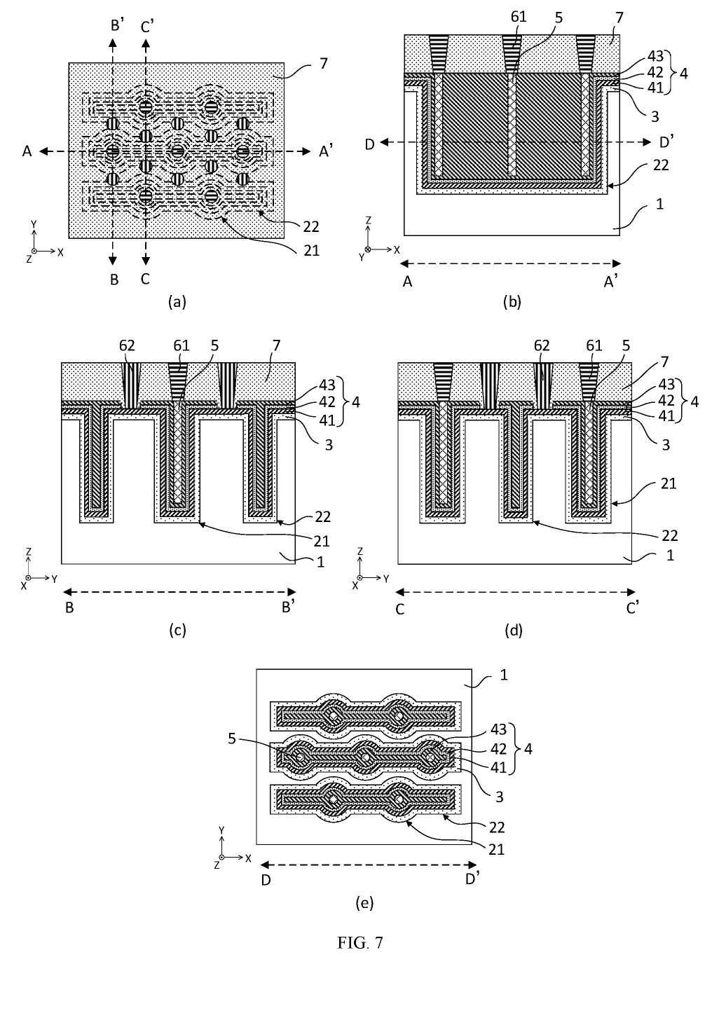

In an exemplary embodiment of the present disclosure, a semiconductor structure is provided. Referring to FIG. 6 or FIG. 7, FIG. 6(a) or FIG. 7(a) is a top view facing the top surface of an interposer 1 in a direction opposite to a Z direction, FIG. 6(b) or FIG. 7(b) is a schematic sectional diagram in a direction A-A’ in FIG. 6(a) or FIG. 7(a), FIG. 6(c) or FIG. 7(c) is a schematic sectional diagram in a direction B-B’ in FIG. 6(a) or FIG. 7(a), FIG. 6(d) or FIG. 7(d) is a schematic sectional diagram in a direction C-C’ in FIG. 6(a) or FIG. 7(a), and FIG. 6(e) or FIG. 7(e) is a schematic sectional diagram in a direction D-D’ in FIG. 6(b) or FIG. 7(b). The semiconductor structure includes: an interposer 1 and a capacitor 4. The interposer 1 is provided with holes 21 and trenches 22 extending from the top surface of the interposer 1 toward the inside of the interposer 1. The capacitor is located in the holes 21 and the trenches 22; the capacitor 4 includes a first electrode layer 41, a capacitor dielectric layer 42, and a second electrode layer 43 which are sequentially stacked; the capacitor dielectric layer 42 covers the surface of the first electrode layer 41, and the second electrode layer 43 covers the surface of the capacitor dielectric layer 42. The trench 22 further extends in a preset direction parallel to the top surface of the interposer 1 and communicates with a plurality of holes 21 spaced apart in the preset direction, the width dimension of the hole 21 is larger than the width dimension of the trench 22, and the direction of the width dimensions is parallel to the top surface of the interposer 1 and perpendicular to the preset direction. It should be noted that, in an exemplary embodiment of the present disclosure, the preset direction and an X direction are in the same direction or in opposite directions, and the direction of the width dimensions and the Y direction are in the same direction or in opposite directions. It should be noted that, in all the drawings of the present disclosure, the X direction, the Y direction, and the Z direction are perpendicular to one another.

In an exemplary embodiment of the present disclosure, the interposer 1 adopts a silicon interposer. The material of the silicon interposer may be at least one of the following materials: silicon, germanium, silicon-on-insulator (SOI), stacked silicon-on-insulator (SSOI), stacked silicon-germanium-on-insulator (S-SiGeOI), silicon-germanium-on-insulator (SiGeOI), germanium-on-insulator (GeOI), and other semiconductor materials, or a combination of group III-V materials and organic materials.

The hole 21 and the trench 22 are located in the interposer 1 and extend from the top surface of the interposer 1 toward the inside of the interposer 1; that is, the openings of the hole 21 and the trench 22 are in the top surface of the interposer 1, and the depth directions of the hole 21 and the trench 22 are perpendicular to a plane where the top surface of the interposer 1 is located and face the inside of the interposer 1, which are opposite to the Z direction in the figure. In a plane parallel to the plane where the top surface of the interposer 1 is located, the trench 22 extends in the preset direction, the holes 21 are spaced apart in the preset direction, with reference to the dotted lines in FIGS. 6(a) or 7(a). The trench 22 extends in the X direction or the opposite direction of the X direction, and communicates with a plurality of holes 21 spaced apart in the X direction or the opposite direction of the X direction. In some embodiments, as shown in FIGS. 6(b) to 6(d) or FIGS. 7(b) to 7(d), the schematic sectional diagram of the hole 21 and/or the trench 22 in the depth direction is rectangular, that is, the opening dimension and the bottom dimension of the hole 21 and/or the trench 22 are substantially the same. In some other embodiments, the schematic sectional diagram of the hole 21 and/or the trench 22 is trapezoidal, for example, the opening dimension of the hole 21 and/or the trench 22 is larger than the bottom dimension, or the bottom dimension of the hole 21 and/or the trench 22 is larger than the opening dimension. In other embodiments, the bottom of the hole 21 and/or the trench 22 is in an arc shape recessing toward the inside of the interposer 1. In some embodiments, the width dimension of the hole 21 is larger than the width dimension of the trench 22. The direction of the width dimensions is parallel to the top surface of the interposer 1 and perpendicular to the preset direction in the foregoing embodiments, that is, the direction of the width dimensions and the Y direction are in the same direction or in opposite directions.

The capacitor 4 is located in the holes 21 and the trenches 22 and includes a first electrode layer 41, a capacitor dielectric layer 42, and a second electrode layer 43 which are sequentially stacked; the capacitor dielectric layer 42 covers the surface of the first electrode layer 41, and the second electrode layer 43 covers the surface of the capacitor dielectric layer 42. In some embodiments, specifically, as shown in FIGS. 6(b) to 6(e) or FIGS. 7(b) to 7(e), a plurality of holes 21, spaced apart in the X direction or the opposite direction of the X direction and communicating with the same trench 22, and the capacitor 4 in the trench 22 are connected as a whole. In some other embodiments, the capacitor 4 further includes one or more other electrode layers (not shown) except for the first electrode layer 41 and the second electrode layer 43, and adjacent electrode layers are separated by the capacitor dielectric layer 42 or an additional capacitor dielectric layer (not shown).

In some embodiments, the material of the first electrode layer 41 and/or the second electrode layer 43 may be a combination of at least one or more of doped silicon, titanium nitride (TiN), silicon-doped titanium nitride (TiSiN), titanium (Ti), tungsten (W), tungsten nitride (WN), and silicon-doped tungsten nitride (WSiN); the material of the capacitor dielectric layer 42 may be a combination of at least one or more of silicon oxide (SiO₂), aluminum oxide (Al₂O₃), zirconium oxide (ZrO₂), hafnium oxide (HfO₂), titanium oxide (TiO₂), tantalum oxide (Ta₂O₅), barium strontium titanate (BST), strontium titanate (STO), and lead titanate (PZT). In an exemplary embodiment of the present disclosure, titanium nitride is used as the material of the first electrode layer 41 and/or the second electrode layer 43, and a high-K (high-K) material is used as the material of the capacitor dielectric layer 42.

In some embodiments, the semiconductor structure further includes: lead-out contact layers 5. The lead-out contact layer is located in the hole 21, covers the surfaces of the second electrode layer 43 located in the hole 21, and fills the hole 21. Specifically, the lead-out contact layer 5 is inserted into the hole 21 in a cylindrical shape and fills the remaining space in the hole 21 excluding the capacitor 4; the lead-out contact layer 5 is located in the hole 21 and shares a central shaft with the hole 21; the hole 21 is in a one-to-one correspondence with the lead-out contact layer 5. In some embodiments, the material of the lead-out contact layer 5 may be a combination of one or more of tungsten (W), molybdenum (Mo), ruthenium (Ru), tantalum (Ta), platinum (Pt), copper (Cu), and/or nitrides thereof. In an exemplary embodiment of the present disclosure, copper is used as the material of the lead-out contact layer 5.

In some embodiments, the semiconductor structure further includes: first contact members 61 and second contact members 62 which are located above the capacitor 4; the first contact member 61 is connected to the lead-out contact layer 5, the second contact member 62 is connected to the first electrode layer 41, and the lead-out contact layer 5 is in a one-to-one correspondence with the first contact member 61. Specifically, the bottom of the first contact member 61 is in direct contact with the top surface of the lead-out contact layer 5. In some embodiments, the first contact member 61 may also be in direct contact with portions of the second electrode layer 43 adjacent to the lead-out contact layer 5; the surface of the capacitor 4 is provided with windows, which open the second electrode layer 43 and the capacitor dielectric layer 42 to expose portions of the top surface of the first electrode layer 41, and the second contact members 62 are in direct contact with the first electrode layer 41 through the windows. In some embodiments, as shown in FIG. 7(a), the first contact members 61 and the second contact members 62 are arranged in a hexagonal close-packed manner, so as to achieve a high integration density on the premise of avoiding short circuits or interference therebetween. In other embodiments, the second contact members 62 may be located at other positions, and the number thereof may be reduced accordingly, but a certain distance between the first contact member 61 and the second contact member 62 is required to avoid short circuits or interference therebetween.

In some embodiments, the material of the first contact member 61 and/or the second contact member 62 may be a combination of one or more of tungsten (W), molybdenum (Mo), ruthenium (Ru), tantalum (Ta), platinum (Pt), copper (Cu), and/or nitrides thereof. In an exemplary embodiment of the present disclosure, tungsten is used as the material of the first contact member 61 and the second contact member 62.

In some embodiments, an interlayer dielectric layer 7 is further provided above the capacitor 4, the interlayer dielectric layer 7 covers the top surface of the capacitor 4, and the first contact member 61 and the second contact member 62 penetrate through the interlayer dielectric layer 7 to be connected to the lead-out contact layer 5 and the first electrode layer 41, respectively. In some embodiments, the material of the interlayer dielectric layer 7 may be at least one or any combination of the following materials: silicon oxide, silicon nitride, silicon oxynitride, silicon oxycarbide, silicon carbonitride, and silicon oxycarbonitride. In an exemplary embodiment of the present disclosure, silicon oxide is used as the material of the interlayer dielectric layer 7.

In some embodiments, the semiconductor structure further includes: a bottom dielectric layer 3. The bottom dielectric layer is located below the capacitor 4 and covers at least the bottoms and the side walls of the hole 21 and the trench 22, the bottom dielectric layer 3 is located between the interposer 1 and the first electrode layer 41, and the first electrode layer 41 covers the surface of the bottom dielectric layer 3. The bottom dielectric layer 3 serves to prevent the interposer 1 from interfering with the electric potential of the first electrode layer 41 and impurities in the interposer 1 from polluting the material of the first electrode layer 41, which may affect the working performance of the capacitor 4. In some embodiments, the material of the bottom dielectric layer 3 may be at least one or any combination of the following materials: silicon oxide, silicon nitride, silicon oxynitride, silicon oxycarbide, silicon carbonitride, and silicon oxycarbonitride. In an exemplary embodiment of the present disclosure, silicon oxide is used as the material of the interlayer dielectric layer 3. In other embodiments, when the purity of the silicon-based material in the interposer 1 is high, the semiconductor structure may be not provided with the bottom dielectric layer 3, the first electrode layer 41 may be in direct contact with the inner surfaces of the hole 21 and the trench 22 in the interposer 1, and even the first electrode layer 41 may be formed by directly doping the inner surfaces of the hole 21 and the trench 22.

In some embodiments, the semiconductor structure includes a plurality of trenches 22, and the plurality of trenches 22 extending in the same preset direction are spaced apart in parallel. As shown in FIGS. 7(a) or 7(e), the plurality of trenches 22 extending in the X direction or the opposite direction of the X direction are spaced apart in the Y direction, and a plurality of holes 21 communicating with adjacent trenches 22 are arranged in a staggered manner in the Y direction or the opposite direction of the Y direction. In some embodiments, the distance between adjacent trenches 22 is equal, and the distance between adjacent holes 21 communicating with the same trench 22 and the distance between adjacent holes 21 communicating with an adjacent trench 22 are equal, that is, the holes 21 are also arranged in a hexagonal close-packed manner.

In an exemplary embodiment of the present disclosure, referring to FIG. 8, the interposer 1 further includes a first region 11 and a second region 12 arranged adjacent to each other. In the first region 11, the preset direction is a first direction, i.e., in the same direction as or in an opposite direction to the X direction; in the second region 12, the preset direction is a second direction, i.e., in the same direction as or in an opposite direction to the Y direction. In some embodiments, the interposer 1 further includes a third region 13 and a fourth region 14 arranged adjacent to each other. The preset directions in the third region 13 and the second region 12 are the same, and the preset directions in the fourth region 14 and the first region 11 are the same; the third region 13 is further arranged adjacent to the first region 11 in the Y direction, and the fourth region 14 is further arranged adjacent to the second region in the Y direction. In some other embodiments, the interposer 1 may include more regions, but the preset directions in adjacent regions are required to be perpendicular to each other. Through the arrangement of regions with preset directions perpendicular to each other, the problems of stress in the interposer 1 and the like can be effectively solved.

According to the semiconductor structure provided in the present disclosure, the trench in the interposer communicates with a plurality of holes, and the capacitor is located in the holes and the trench, such that the area of the capacitor is effectively increased, and the capacity of the capacitor is improved, thereby improving the performance of the capacitor. The hole is further provided with a lead-out contact layer made of a material with high conductivity, and meanwhile, the lead-out contact layer is connected to the first contact member in a one-to-one correspondence manner, such that the rapid charge and discharge requirements of the capacitor can be met. Holes communicating with adjacent trenches extending in the preset direction are arranged in a staggered manner in a direction perpendicular to the preset direction, such that the area utilization rate is greatly improved, and thus the integration of a capacitor device is improved. The preset directions in which the trenches extend in adjacent regions in the interposer are perpendicular to each other, such that the problems of stress in the interposer and the like are effectively solved. In conclusion, the semiconductor structure provided in the present disclosure has the advantages of large capacity, rapid charge and discharge, and high integration, such that the device performance of the DTC structure is greatly improved, and the layout of the semiconductor structure also has a better improvement effect on the stress in the interposer.

Based on the above semiconductor structure, the present disclosure further provides a method for manufacturing a semiconductor structure. The method includes the following steps: An interposer 1 is provided, as shown in FIG. 1, where FIG. 1(a) is a top view facing the interposer 1 in the direction opposite to the Z direction, and FIG. 1(b) is a schematic sectional diagram in a dotted line A-A’ direction in FIG. 1(a), the section in the dotted line A-A’ direction being perpendicular to the top surface of the interposer 1.

In an exemplary embodiment of the present disclosure, the interposer 1 adopts a silicon interposer. The material of the silicon interposer may be at least one of the following materials: silicon, germanium, silicon-on-insulator (SOI), stacked silicon-on-insulator (SSOI), stacked silicon-germanium-on-insulator (S-SiGeOI), silicon-germanium-on-insulator (SiGeOI), germanium-on-insulator (GeOI), and other semiconductor materials, or a combination of group III-V materials and organic materials.

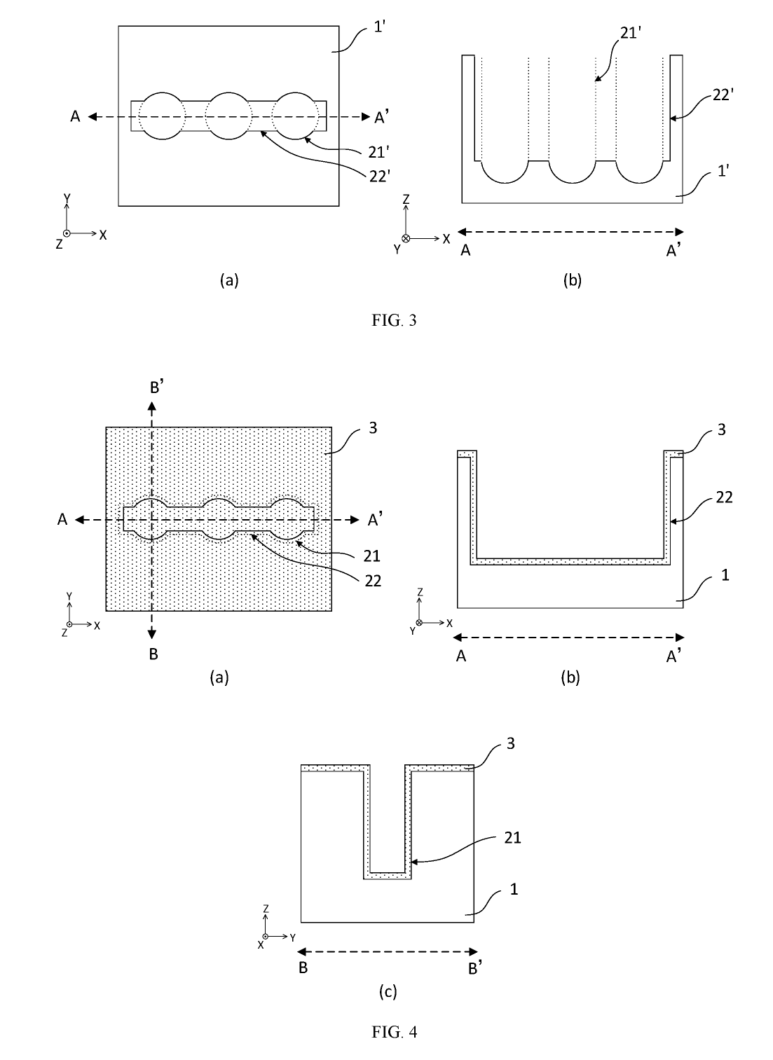

Next, holes 21 and trenches 22 extending from the top surface of the interposer 1 toward the inside of the interposer 1 are formed in the interposer 1. Referring to FIG. 2 or FIG. 3, FIG. 2(a)/3(a) is a top view facing the interposer 1 in the direction opposite to the Z direction, FIG. 2(b)/3(b) is a schematic sectional diagram in the dotted line A-A’ direction in FIG. 2(a)/3(a), and the section in the dotted line A-A’ direction is perpendicular to the top surface of the interposer 1. Specifically, the hole 21 and the trench 22 with a certain depth are formed by etching from the surface of the interposer 1 toward the inside of the interposer 1, that is, the openings of the hole 21 and the trench 22 are in the top surface of the interposer 1, and the depth directions of the hole 21 and the trench 22 are perpendicular to a plane where the top surface of the interposer 1 is located and face the inside of the interposer 1, which are opposite to the Z direction in the figure. In a plane parallel to the plane where the top surface of the interposer 1 is located, the trench 22 extends in the preset direction, the holes 21 are spaced apart in the preset direction. In FIG. 2, the preset direction may be the X direction or the opposite direction of the X direction. The trench 22 extends in the X direction or the opposite direction of the X direction, and communicates with a plurality of holes 21 spaced apart in the X direction or the opposite direction of the X direction. In some embodiments, as shown in FIGS. 2(a) or 3(a), the width dimension of the hole 21 is larger than the width dimension of the trench 22. The direction of the width dimensions is parallel to the top surface of the interposer 1 and perpendicular to the preset direction in the foregoing embodiments, that is, the direction of the width dimensions and the Y direction are in the same direction or in opposite directions. In some embodiments, the schematic sectional diagram of the hole 21 and/or the trench 22 in the depth direction is rectangular, that is, the opening dimension and the bottom dimension of the hole 21 and/or the trench 22 are substantially the same. In some other embodiments, the schematic sectional diagram of the hole 21 and/or the trench 22 is trapezoidal, for example, the opening dimension of the hole 21 and/or the trench 22 is larger than the bottom dimension, or the bottom dimension of the hole 21 and/or the trench 22 is larger than the opening dimension. In an exemplary embodiment of the present disclosure, as shown in FIG. 2(b), the hole 21 and the trench 22 have the same depth. In another exemplary embodiment of the present disclosure, as shown in FIG. 3(b), the depth of the hole 21 is larger than that of the trench 22. It is due to the fact that the hole 21 has a larger width dimension, and thus, in the synchronous adaptive etching process, the larger opening dimension tends to correspond to the larger etching depth. In other embodiments, the depths of the hole 21 and the trench 22 can be controlled by step-by-step etching, respectively.

In some embodiments, the photoetching process may be used to etch the surface of the interposer 1 to form the hole 21 and/or the trench 22. Specifically, a photoresist mask layer may be formed on the surface of the interposer 1, the pattern of the hole 21 and/or the trench 22 may be formed in the photoresist mask layer through exposure and development, and then dry etching may be performed to etch the interposer 1 along the pattern to form the hole 21 and/or the trench 22. In some embodiments, before coating the photoresist mask layer, the step of forming an anti-reflection layer and a hard mask layer (not shown) on the surface of the interposer 1 is further included. Further, the anti-reflection layer and the hard mask layer are removed after forming the hole 21 and/or the trench 22. In some embodiments, the hole 21 and the trench 22 are formed by simultaneous etching; that is, in exposure and development, the patterns of the hole 21 and the trench 22 are both formed in the photoresist mask layer (the combination of two patterns of the hole 21 and the trench 22 may be exposed in a single exposure process, or two patterns of the hole 21 and the trench 22 may be exposed in a double exposure process, respectively), and then etched to form the hole and the trench. In some other embodiments, the hole 21 and the trench 22 are formed by step-by-step etching; that is, the hole 21 may be formed by the first photoetching, and then the trench 22 may be formed by the second photoetching, where the order of forming the hole 21 and the trench 22 may also be reversed.

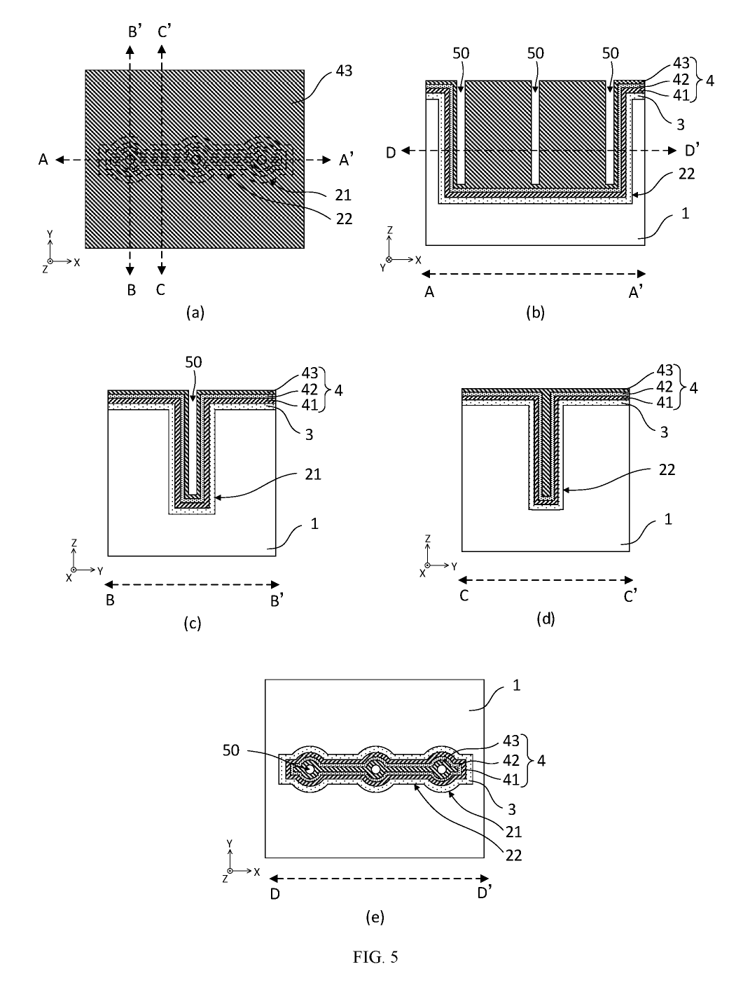

Next, in an exemplary embodiment of the present disclosure, a bottom dielectric layer 3 is formed in the hole 21 and the trench 22, covering at least the bottoms and the side walls of the hole 21 and the trench 22. As shown in FIG. 4, FIG. 4(a) is a top view facing the interposer 1 in the direction opposite to the Z direction, FIG. 4(b) is a schematic sectional diagram in the dotted line A-A’ direction in FIG. 4(a), and FIG. 4(c) is a schematic sectional diagram in a dotted line B-B’ direction in FIG. 4(a); the section in the dotted line A-A’ direction and the section in the dotted line B-B’ direction are perpendicular to each other and are both perpendicular to the top surface of the interposer 1.

In some embodiments, the material of the bottom dielectric layer 3 may be at least one or any combination of the following materials: silicon oxide, silicon nitride, silicon oxynitride, silicon oxycarbide, silicon carbonitride, and silicon oxycarbonitride. In an exemplary embodiment of the present disclosure, silicon oxide is used as the material of the bottom dielectric layer 3. In some embodiments, the deposition method for the bottom dielectric layer 3 may adopt at least one of the following deposition methods: chemical vapor deposition (CVD), low pressure chemical vapor deposition (LPCVD), plasma enhanced chemical vapor deposition (PECVD), ultra-high vacuum chemical vapor deposition (UHVCVD), flowable chemical vapor deposition (FCVD), direct liquid injection chemical vapor deposition (DLICVD), rapid thermal chemical vapor deposition (RTCVD), microwave plasma-assisted chemical vapor deposition (MPCVD), metal-organic chemical vapor deposition (MOCVD), atomic layer deposition (ALD), spin-on dielectric layer (SOD), in-situ steam generation (ISSG), and a thermal oxidation growth method.

Then, a capacitor 4, composed of a first electrode layer 41, a capacitor dielectric layer 42, and a second electrode layer 43 which are sequentially stacked, is formed in the hole 21 and the trench 22. The capacitor dielectric layer 42 covers the surface of the first electrode layer 41, and the second electrode layer 43 covers the surface of the capacitor dielectric layer 42. Referring to FIG. 5, FIG. 5(a) is a top view facing the interposer 1 in the direction opposite to the Z direction, FIG. 5(b) is a schematic sectional diagram in the dotted line A-A’ direction in FIG. 5(a), FIG. 5(c) is a schematic sectional diagram in the dotted line B-B’ direction in FIG. 5(a), FIG. 5(d) is a schematic sectional diagram in a dotted line C-C’ direction in FIG. 5(a), and FIG. 5(e) is a schematic sectional diagram in a dotted line D-D’ direction in FIG. 5(b); the section in the dotted line A-A’ direction and the section in the dotted line B-B’ direction are perpendicular to each other and are both perpendicular to the top surface of the interposer 1, the section in the dotted line C-C’ direction is parallel to the section in the dotted line B-B’ direction, and the section in the dotted line D-D’ direction is parallel to the top surface of the interposer 1.

In some embodiments, after forming the capacitor 4, the trenches 22 are filled with the material of the capacitor 4, as shown in FIG. 5(d); however, the holes 21 are not filled and thus gaps 50 are formed, as shown in FIGS. 5(b) and 5(c); the gaps 50 are in a one-to-one correspondence with the holes 21 and are spaced apart in the preset direction. The second electrode layer 43 in the holes 21 defines the gaps 50 in an enclosing manner. In some embodiments, the capacitor 4 also extends to cover the top surface of the interposer 1.

In some embodiments, the bottom dielectric layer 3 is located between the interposer 1 and the first electrode layer 41, and the first electrode layer 41 covers the surface of the bottom dielectric layer 3. The bottom dielectric layer 3 serves to prevent the interposer 1 from interfering with the electric potential of the first electrode layer 41 and impurities in the interposer 1 from polluting the material of the first electrode layer 41, which may affect the working performance of the capacitor 4. In other embodiments, when the purity of the silicon-based material in the interposer 1 is high, the semiconductor structure may be not provided with the bottom dielectric layer 3, the first electrode layer 41 may be in direct contact with the inner surfaces of the hole 21 and the trench 22 in the interposer 1, and even the first electrode layer 41 may be formed by directly doping the inner surfaces of the hole 21 and the trench 22.

In some embodiments, the material of the first electrode layer 41 and/or the second electrode layer 43 may be a combination of at least one or more of doped silicon, titanium nitride (TiN), silicon-doped titanium nitride (TiSiN), titanium (Ti), tungsten (W), tungsten nitride (WN), and silicon-doped tungsten nitride (WSiN); the material of the capacitor dielectric layer 42 may be a combination of at least one or more of silicon oxide (SiO₂), aluminum oxide (Al₂O₃), zirconium oxide (ZrO₂), hafnium oxide (HfO₂), titanium oxide (TiO₂), tantalum oxide (Ta₂O₅), barium strontium titanate (BST), strontium titanate (STO), and lead titanate (PZT). In an exemplary embodiment of the present disclosure, titanium nitride is used as the material of the first electrode layer 41 and/or the second electrode layer 43, and a high-K (high-K) material is used as the material of the capacitor dielectric layer 42.

In some embodiments, the formation method for the first electrode layer 41, the capacitor dielectric layer 42, and the second electrode layer 43 may adopt at least one of the following deposition methods: chemical vapor deposition (CVD), low pressure chemical vapor deposition (LPCVD), plasma enhanced chemical vapor deposition (PECVD), ultra-high vacuum chemical vapor deposition (UHVCVD), flowable chemical vapor deposition (FCVD), direct liquid injection chemical vapor deposition (DLICVD), rapid thermal chemical vapor deposition (RTCVD), microwave plasma-assisted chemical vapor deposition (MPCVD), metal-organic chemical vapor deposition (MOCVD), atomic layer deposition (ALD), physical vapor deposition (PVD), and sputtering.

Next, a lead-out contact layer 5 is formed in the hole 21, covering the surface of the second electrode layer 43 located in the hole 21 and filling the hole 21. As shown in FIG. 6, FIG. 6(a) is a top view facing the interposer 1 in the direction opposite to the Z direction, FIG. 6(b) is a schematic sectional diagram in the dotted line A-A’ direction in FIG. 6(a), FIG. 6(c) is a schematic sectional diagram in the dotted line B-B’ direction in FIG. 6(a), FIG. 6(d) is a schematic sectional diagram in the dotted line C-C’ direction in FIG. 6(a), and FIG. 6(e) is a schematic sectional diagram in the dotted line D-D’ direction in FIG. 6(b); the section in the dotted line A-A’ direction and the section in the dotted line B-B’ direction are perpendicular to each other and are both perpendicular to the top surface of the interposer 1, the section in the dotted line C-C’ direction is parallel to the section in the dotted line B-B’ direction, and the section in the dotted line D-D’ direction is parallel to the top surface of the interposer 1.

Specifically, the lead-out contact layer 5 is inserted into the hole 21 in a cylindrical shape and fills the gap 50 remaining in the hole 21 after forming the capacitor 4; the lead-out contact layer 5 is located in the hole 21 and shares a central shaft with the hole 21; the hole 21 is in a one-to-one correspondence with the lead-out contact layer 5. In some embodiments, the material filling the lead-out contact layer 5 may escape the gap 50, and the excess material may be subsequently removed by back etching or a planarization process, such that the top surface of the lead-out contact layer 5 is at the same height as the top surface of the second electrode layer 43.

In some embodiments, the material of the lead-out contact layer 5 may be a combination of one or more of tungsten (W), molybdenum (Mo), ruthenium (Ru), tantalum (Ta), platinum (Pt), copper (Cu), and/or nitrides thereof. In an exemplary embodiment of the present disclosure, copper is used as the material of the lead-out contact layer 5. In some embodiments, the formation method for the lead-out contact layer 5 may adopt at least one of the following deposition methods: chemical vapor deposition (CVD), low pressure chemical vapor deposition (LPCVD), plasma enhanced chemical vapor deposition (PECVD), ultra-high vacuum chemical vapor deposition (UHVCVD), flowable chemical vapor deposition (FCVD), direct liquid injection chemical vapor deposition (DLICVD), rapid thermal chemical vapor deposition (RTCVD), microwave plasma-assisted chemical vapor deposition (MPCVD), metal-organic chemical vapor deposition (MOCVD), atomic layer deposition (ALD), physical vapor deposition (PVD), and sputtering.

Next, with continued reference to FIG. 6, first contact members 61 and second contact members 62 are formed above the capacitor 4; the first contact member 61 is connected to the lead-out contact layer 5, the second contact member 62 is connected to the first electrode layer 41, and the lead-out contact layer 5 is in a one-to-one correspondence with the first contact member 61. Specifically, the bottom of the first contact member 61 is in direct contact with the top surface of the lead-out contact layer 5. In some embodiments, the first contact member 61 may also be in direct contact with portions of the second electrode layer 43 adjacent to the lead-out contact layer 5; the surface of the capacitor 4 is provided with windows, which open the second electrode layer 43 and the capacitor dielectric layer 42 to expose portions of the top surface of the first electrode layer 41, and the second contact members 62 are in direct contact with the first electrode layer 41 through the windows.

In some embodiments, the material of the first contact member 61 and/or the second contact member 62 may be a combination of one or more of tungsten (W), molybdenum (Mo), ruthenium (Ru), tantalum (Ta), platinum (Pt), copper (Cu), and/or nitrides thereof. In an exemplary embodiment of the present disclosure, tungsten is used as the material of the first contact member 61 and the second contact member 62. In some embodiments, the formation method for the first contact member 61 and/or the second contact member 62 may adopt at least one of the following deposition methods: chemical vapor deposition (CVD), low pressure chemical vapor deposition (LPCVD), plasma enhanced chemical vapor deposition (PECVD), ultra-high vacuum chemical vapor deposition (UHVCVD), flowable chemical vapor deposition (FCVD), direct liquid injection chemical vapor deposition (DLICVD), rapid thermal chemical vapor deposition (RTCVD), microwave plasma-assisted chemical vapor deposition (MPCVD), metal-organic chemical vapor deposition (MOCVD), atomic layer deposition (ALD), physical vapor deposition (PVD), and sputtering.

In some embodiments, before forming the first contact member 61 and the second contact member 62, the step of forming an interlayer dielectric layer 7 to cover the top surface of the capacitor 4 is further included. The first contact member 61 and the second contact member 62 penetrate through the interlayer dielectric layer 7 to be connected to the lead-out contact layer 5 and the first electrode layer 41, respectively. Specifically, the interlayer dielectric layer 7 is formed on the capacitor 4 to cover the top surfaces of the second electrode layer 43 and the lead-out contact layer 5, and the interlayer dielectric layer 7 is then etched to form first through holes and second through holes. The first through holes penetrate through the interlayer dielectric layer 7 and expose at least the top surfaces of the lead-out contact layers 5; the second through holes penetrate through the interlayer dielectric layer 7, and windows are formed on the surface of the capacitor 4; the windows open the second electrode layer 43 and the capacitor dielectric layer 42 to expose portions of the top surface of the first electrode layer 41, and the first contact members 61 are formed by filling the first through holes and the second contact members 62 are formed by filling the second through holes, respectively. In some embodiments, the bottom of the first contact member 61 is in direct contact with the top surface of the lead-out contact layer 5, and may also be in direct contact with portions of the second electrode layer 43 adjacent to the lead-out contact layer 5; the bottom of the second contact member 62 is in direct contact with the exposed portion of the top surface of the first electrode layer 41.

In some embodiments, the material of the interlayer dielectric layer 7 may be at least one or any combination of the following materials: silicon oxide, silicon nitride, silicon oxynitride, silicon oxycarbide, silicon carbonitride, and silicon oxycarbonitride. In an exemplary embodiment of the present disclosure, silicon oxide is used as the material of the interlayer dielectric layer 7. In some embodiments, the deposition method for the interlayer dielectric layer 7 may adopt at least one of the following deposition methods: chemical vapor deposition (CVD), low pressure chemical vapor deposition (LPCVD), plasma enhanced chemical vapor deposition (PECVD), ultra-high vacuum chemical vapor deposition (UHVCVD), flowable chemical vapor deposition (FCVD), direct liquid injection chemical vapor deposition (DLICVD), rapid thermal chemical vapor deposition (RTCVD), microwave plasma-assisted chemical vapor deposition (MPCVD), metal-organic chemical vapor deposition (MOCVD), atomic layer deposition (ALD), spin-on dielectric layer (SOD), in-situ steam generation (ISSG), and a thermal oxidation growth method.

In another exemplary embodiment of the present disclosure, a plurality of trenches 22 extending in the preset direction are formed in the interposer 1, the plurality of trenches 22 are spaced apart in a direction perpendicular to the preset direction, and in the direction perpendicular to the preset direction, a plurality of holes 21 communicating with adjacent trenches 22 are arranged in a staggered manner. As shown in FIG. 7, FIG. 7(a) is a top view facing the interposer 1 in the direction opposite to the Z direction, FIG. 7(b) is a schematic sectional diagram in the dotted line A-A’ direction in FIG. 7(a), FIG. 7(c) is a schematic sectional diagram in the dotted line B-B’ direction in FIG. 7(a), FIG. 7(d) is a schematic sectional diagram in the dotted line C-C’ direction in FIG. 7(a), and FIG. 7(e) is a schematic sectional diagram in the dotted line D-D’ direction in FIG. 7(b); the section in the dotted line A-A’ direction and the section in the dotted line B-B’ direction are perpendicular to each other and are both perpendicular to the top surface of the interposer 1, the section in the dotted line C-C’ direction is parallel to the section in the dotted line B-B’ direction, and the section in the dotted line D-D’ direction is parallel to the top surface of the interposer 1.

In this embodiment, except for the step of the method that the plurality of trenches 22 extending in the preset direction and spaced apart in the direction perpendicular to the preset direction are simultaneously formed, all the other subsequent steps of the formation methods for the bottom dielectric layer 3, the capacitor 4, and the lead-out contact layer 5 in the trench 22 and the hole 21, the interlayer dielectric layer 7, the first contact member 61, and the second contact member 62 are the same as those described in the foregoing embodiments, which will not be reiterated herein.

In some embodiments, as shown in FIGS. 7(a) to 7(e), the holes 21 and the lead-out contact layers 5 are both arranged in a hexagonal close-packed manner, and the first contact members 61 and the second contact members 62 may be arranged in a hexagonal close-packed manner with a higher density, so as to achieve a high integration density on the premise of avoiding short circuits or interference therebetween. In other embodiments, the second contact members 62 may be located at other positions, and the number thereof may be reduced accordingly, but a certain distance between the first contact member 61 and the second contact member 62 is required to avoid short circuits or interference therebetween.

In some embodiments of the present disclosure, referring to FIG. 8, the interposer 1 further includes a first region 11 and a second region 12 arranged adjacent to each other. In the first region 11, the preset direction is a first direction, i.e., in the same direction as or in an opposite direction to the X direction; in the second region 12, the preset direction is a second direction, i.e., in the same direction as or in an opposite direction to the Y direction. In some embodiments, the interposer 1 further includes a third region 13 and a fourth region 14 arranged adjacent to each other. The preset directions in the third region 13 and the second region 12 are the same, and the preset directions in the fourth region 14 and the first region 11 are the same; the third region 13 is further arranged adjacent to the first region 11 in the Y direction, and the fourth region 14 is further arranged adjacent to the second region in the Y direction. In some other embodiments, the interposer 1 may include more regions, but the preset directions in adjacent regions are required to be perpendicular to each other. Through the arrangement of regions with preset directions perpendicular to each other, the problems of stress in the interposer 1 and the like can be effectively solved.

In the aforementioned embodiments, the step of forming the plurality of trenches 22 extending in different preset directions and the holes 21 penetrated by the trenches in different regions, and the subsequent steps of the formation methods for the bottom dielectric layer 3, the capacitor 4, and the lead-out contact layer 5 in the trench 22 and the hole 21, the interlayer dielectric layer 7, the first contact member 61, and the second contact member 62 can all be performed synchronously and are the same as those described in the foregoing embodiments, which will not be reiterated herein.

In an exemplary embodiment of the present disclosure, a semiconductor device is further provided. As shown in FIG. 9, the semiconductor device includes at least the semiconductor structure 101 according to any one of the foregoing embodiments, and chips 201 located above the semiconductor structure 101, where the chips 201 and the semiconductor structure 101 are electrically connected through solder bumps 401 and/or pads (not shown). In other embodiments, the chips 201 and the semiconductor structure may also be electrically connected by a wire bond (wire bond) method. In some embodiments, the interposer 1 in the semiconductor structure 101 further includes interconnection structures such as a re-distribution layer (re-distribution layer, RDL) 1011 and through silicon vias (TSVs) 1012. In some embodiments, the chip 201 may be a plurality of mutually stacked memory chips, e.g., a dynamic random access memory (DRAM) chip or a Not AND (NAND) FLASH chip, and the chips 201 may be interconnected by bumps (bumps) or hybrid bonding (hybrid bonding), and through silicon vias (TSVs) 202. In some other embodiments, the chip 201 may also be a processor chip or an image sensor chip. In some embodiments, the semiconductor device further includes: a substrate 301, on which the semiconductor structure 101 is located. The substrate 301 and the semiconductor structure 101 may also be electrically connected through solder bumps 402. In some embodiments, the substrate 301 may be a glass substrate, an organic substrate, or an insulating substrate, and the substrate 301 further includes solder bumps 403 below for connecting to a main board or other PCBs.

It should be noted that the semiconductor structure or the semiconductor device in the embodiments of the present disclosure can be used to manufacture a packaging structure of a memory chip, and can also be used to manufacture other devices that require a capacitor structure to be manufactured in an interposer, which is not overly limited herein.

The various semiconductor structures shown in the specific embodiments can be used for an electronic device having a memory function. The electronic device may be a terminal device, e.g., a mobile phone, a tablet computer, a smart bracelet, a personal computer (personal computer, PC), a server, or a workstation. The memory function in the electronic device can be implemented by using the following memories: a dynamic random access memory (DRAM), a ferroelectric random access memory (FRAM), a phase change memory (PCM), a magnetic random access memory (MRAM), a resistive random access memory (RRAM), a flash memory (FLASH), or some integrated storage products or system on chips.

The above description is only the specific embodiments of the present disclosure, but the protection scope of the present disclosure is not limited thereto; changes or substitutions that any of those skilled in the art can easily think of within the technical scope disclosed by the present disclosure shall all fall within the protection scope of the present disclosure. Therefore, the protection scope of the present disclosure shall be defined by the protection scope of the claims.

What is claimed is:

1. A semiconductor structure, comprising:
an interposer, wherein the interposer is provided with holes and trenches extending from a top surface of the interposer toward an inside of the interposer; and
a capacitor, located in the holes and the trenches, wherein the capacitor comprises a first electrode layer, a capacitor dielectric layer, and a second electrode layer which are sequentially stacked, the capacitor dielectric layer covers a surface of the first electrode layer, and the second electrode layer covers a surface of the capacitor dielectric layer,
wherein each of the trenches further extends in a preset direction parallel to the top surface of the interposer and communicates with a plurality of holes spaced apart in the preset direction, a width dimension of each of the holes is larger than a width dimension of the trench, and a direction of width dimensions is parallel to the top surface of the interposer and perpendicular to the preset direction.

2. The semiconductor structure according to claim 1, further comprising: lead-out contact layers, wherein the lead-out contact layers are located in the holes, cover surfaces of the second electrode layer located in the holes, and fill the holes.

3. The semiconductor structure according to claim 2, wherein a material of the lead-out contact layers comprises copper.

4. The semiconductor structure according to claim 2, further comprising: first contact members and second contact members located above the capacitor, wherein the first contact members are connected to the lead-out contact layers, and the second contact members are connected to the first electrode layer.

5. The semiconductor structure according to claim 4, wherein both the holes and the lead-out contact layers, and both the lead-out contact layers and the first contact members, are in a one-to-one correspondence.

6. The semiconductor structure according to claim 1, wherein the interposer comprises a plurality of trenches, and in a direction perpendicular to the preset direction, a plurality of holes communicating with adjacent trenches are arranged in a staggered manner.

7. The semiconductor structure according to claim 1, wherein the interposer further comprises a first region and a second region arranged adjacent to each other, wherein in the first region, the preset direction is a first direction, and in the second region, the preset direction is a second direction, the first direction and the second direction being perpendicular to each other.

8. The semiconductor structure according to claim 7, wherein in the first region, a plurality of trenches extend in the first direction and are spaced apart in the second direction, and in the second region, a plurality of trenches extend in the second direction and are spaced apart in the first direction.

9. The semiconductor structure according to claim 1, further comprising: a bottom dielectric layer, covering at least bottoms and side walls of the holes and the trenches, wherein the bottom dielectric layer is located between the interposer and the first electrode layer, and the first electrode layer covers a surface of the bottom dielectric layer.

10. A method for manufacturing a semiconductor structure, comprising:
providing an interposer;
forming holes and trenches extending from a top surface of the interposer toward an inside of the interposer in the interposer; and
forming a capacitor, composed of a first electrode layer, a capacitor dielectric layer, and a second electrode layer which are sequentially stacked, in the holes and the trenches, wherein the capacitor dielectric layer covers a surface of the first electrode layer, and the second electrode layer covers a surface of the capacitor dielectric layer,
wherein each of the trenches further extends in a preset direction parallel to the top surface of the interposer and communicates with a plurality of holes spaced apart in the preset direction, a width dimension of each of the holes is larger than a width dimension of the trench, and a direction of width dimensions is parallel to the top surface of the interposer and perpendicular to the preset direction.

11. The method for manufacturing a semiconductor structure according to claim 10, further comprising: forming lead-out contact layers in the holes, wherein the lead-out contact layers cover surfaces of the second electrode layer located in the holes and fill the holes.

12. The method for manufacturing a semiconductor structure according to claim 11, further comprising: forming first contact members and second contact members above the capacitor, wherein the first contact members are connected to the lead-out contact layers, and the second contact members are connected to the first electrode layer,
wherein both the holes and the lead-out contact layers, and both the lead-out contact layers and the first contact members, are in a one-to-one correspondence.

13. The method for manufacturing a semiconductor structure according to claim 12, wherein the interposer further comprises a first region and a second region arranged adjacent to each other, wherein in the first region, the preset direction is a first direction, and in the second region, the preset direction is a second direction, the first direction and the second direction being perpendicular to each other; and
forming the holes and the trenches extending from the top surface of the interposer toward the inside of the interposer in the interposer comprises:
forming a plurality of trenches extending in the first direction and spaced apart in the second direction in the first region, and forming a plurality of trenches extending in the second direction and spaced apart in the first direction in the second region, wherein in a direction perpendicular to the preset direction, a plurality of holes communicating with adjacent trenches are arranged in a staggered manner.

14. The method for manufacturing a semiconductor structure according to claim 10, further comprising: before forming the capacitor in the holes and the trenches, forming a bottom dielectric layer in the holes and the trenches, wherein the bottom dielectric layer covers at least bottoms and side walls of the holes and the trenches; and
the bottom dielectric layer is located between the interposer and the first electrode layer formed subsequently, the first electrode layer covering a surface of the bottom dielectric layer.

15. A semiconductor device, comprising:
the semiconductor structure according to claim 1; and
chips, located above the semiconductor structure,
wherein the chips and the semiconductor structure are electrically connected through solder bumps and/or pads.
